(19) United States
(12) Patent Application Publication
(10) Pub. No.: US 2024/0074117 A1
(43) Pub. Date: Feb. 29, 2024

(54) METHOD AND MOBILE UNIT FOR FLEXIBLE ENERGY OPTIMISATION BETWEEN COMPUTING MODULES AND A GREENHOUSE, OTHER BUILDING OR INDUSTRIAL PROCESS EQUIPMENT TO BE HEATED USING IMMERSION COOLING

(71) Applicant: Sustainable Data Farming B.V., Hoofddorp (NL)

(72) Inventors: Jacob Jan Ten Wolde, Hoofddorp (NL); Jelmer Durk Ten Wolde, Hoofddorp (NL); Patrick Christiaan Bakker, Zuidoostbeemster (NL); Dirk Bakker, Zuidoostbeemster (NL)

(21) Appl. No.: 18/280,298

(22) PCT Filed: Mar. 4, 2022
(86) PCT No.: PCT/EP2022/055628

§ 371 Date: Sep. 5, 2023

(30) Foreign Application Priority Data
Mar. 5, 2021 (NL) 2027716

(51) Int. Cl. H05K 7/20

(52) U.S. Cl. CPC H05K 7/20763

(57) ABSTRACT

A method for energy optimisation between computing modules and a greenhouse, other building or industrial process equipment to be heated, including the steps placing a mobile unit at a site of the greenhouse, other building or industrial process equipment to be heated, including one or more computing modules, a cooling arrangement for cooling the computing modules including one or more closed-loop coolant circuits having an immersion enclosure and a pump; arranging the computing modules in the immersion enclosure of each of the one or more coolant circuits; and filling the immersion enclosure with liquid coolant to at least partially immerse the computing modules in the liquid coolant, performing computing tasks with the computing modules whereby heat is generated; and guiding the generated heat away from the computing modules towards the greenhouse, other building or industrial process equipment to be heated by means of immersion cooling with the liquid coolant.

### CROSS-REFERENCE TO RELATED APPLICATIONS

This application is the National Stage of International Application No. PCT/EP2022/055628, filed Mar. 4, 2022, which claims the benefit of Netherlands Application No. 2027716, filed Mar. 5, 2021, the contents of which is incorporated by reference herein.

### FIELD OF THE INVENTION

The present invention relates to a method for flexible energy optimisation between computing modules and a greenhouse, other building or industrial process equipment to be heated, a mobile unit for flexible energy optimisation between computing modules and a greenhouse, other building or industrial process equipment to be heated, an assembly for flexible energy optimisation between a mobile unit with computing modules and a greenhouse, other building or industrial process equipment to be heated and use thereof.

### BACKGROUND OF THE INVENTION

In horticulture, there is a continued demand for heat, light and CO2, depending on various factors, such as on the crop being cultivated, a cultivation phase and environmental conditions, such as sunlight and outdoor temperature.

An energy source, such as a combined heat-power (CHP) generator, can be used to at least partially meet this demand. The electricity that is generated by the CHP generator may be used to meet electricity demand of the greenhouse, for example for powering assimilation lighting, ventilation means or watering means, while excess electricity then may be fed back into the public utility grid. Such a CHP generator usually burns a fuel, like natural gas, and thereby simultaneously creates heat that can be used for heating the greenhouse, whereby the CO2 that arises during combustion can be supplied to the crops. When the generated electricity, heat and CO2 are all used, approximately 51% of the energy from the fuel may be converted into electricity and approximately 47% may be converted into heat, such that very high energy efficiencies of 98% can be achieved if both the heat and the electricity generated by the CHP can be used effectively.

However, the amounts of heat, electricity and CO2 generated by the CHP generator are mostly not all together in line with the demands in the greenhouse at a same time. For example, a heat demand may be comparatively higher than an electricity demand. Additionally, the feed-in tariff for electricity that is fed back into the grid, is increasingly subject to fluctuation lately, due to an increasing amount of sustainable electricity sources, like solar energy and wind energy. As a result, it is not always possible and/or economic to feed all excess generated electricity back into the grid, which reduces utilisation and/or efficiency of the CHP generator and/or which causes a conventional heating system, such as a boiler, to be required for heating the greenhouse.

An alternative, sustainable way to meet the heat demand would be to use residual heat from a data centre. In data centres, residual heat is often dissipated into the environment and thus wasted. However, data centres and greenhouses are often located at a large distance from each other, such that costs for using residual heat from such data centres are usually high and/or large heat losses occur, that may exceed 30% in a typical large-distance heating network.

WO2019086523 discloses a mobile unit comprising computing modules that are arranged in a container, having air inlets and pipes to distribute cooling air amongst the computing modules. Cooling air heated by the computing modules may be blown into an air conditioning system of a building or directly into that building for heating purposes, for example into a greenhouse. As the computing modules are provided in the container, the mobile unit may be positioned closely to where the heated air can conveniently be used.

A disadvantage of the known mobile unit is that the maximum amount of heat that can be generated and subsequently transferred to the building has appeared to be limited and requires large radiators/convectors to properly heat the building. Another disadvantage is that the computing modules may obtain relatively high temperatures during operation and therefore must have relatively large cooling surfaces for the required air cooling to be sufficient.

As a result, only a limited number of modules can be provided inside the container.

Furthermore, it has been found that the lifespan of the computing modules in the known mobile unit is relatively low and such the computing modules need to be replaced frequently.

Yet another disadvantage is that, the unit's ventilators may be noisy, for example during 24 hours a day, and that, when a maximum ventilation capacity is reached, the computing modules must be switched off in order to prevent them from getting overheated. As fresh air is continuously drawn in from the environment, air filters are necessary to reduce pollution and decline of the computing modules.

### Object of the Invention

It is an object of the present invention to provide an improved method and mobile unit for flexible energy optimisation between computing modules and a greenhouse, other building or industrial process equipment to be heated, which overcomes one or more of the disadvantages of the prior art, or at least to provide an alternative method and mobile unit for energy optimisation between computing modules and a greenhouse, other building or industrial process equipment to be heated, for example a method that is more sustainable and reduces fuel consumption for heating

### The Present Invention

The present invention provides a method for energy optimisation between computing modules and a greenhouse, other building or industrial process equipment to be heated, comprising the following steps: A mobile unit is placed at a site of the greenhouse, other building or industrial process equipment to be heated, wherein the mobile unit comprises one or more computing modules for performing computing tasks, a cooling arrangement for cooling the computing modules, and an electric connector for connecting the computing modules with an electricity source. The electric connector is connected to the electricity source, and the cooling arrangement is coupled to the greenhouse, other building or industrial process equipment to be heated. Computing tasks are performed with the computing modules whereby heat is generated, and the generated heat is guided away from the computing modules towards the greenhouse, other building or industrial process equipment to be heated.

According to the inventive thought, the cooling arrangement comprises one or more closed-loop coolant circuits having an immersion enclosure, a heat exchanger and a pump, and the method further comprises the following steps: the computing modules are arranged in the immersion enclosure of each of the one or more coolant circuits, and the immersion enclosure is filled with liquid coolant to at least partially immerse the computing modules in the liquid coolant.

The step of coupling the cooling arrangement to the greenhouse, other building or industrial process equipment to be heated comprises coupling the heat exchanger of each of the one or more coolant circuits to a heating system of the greenhouse, other building or industrial process equipment to be heated. During the step of performing computing tasks with the computing modules, the liquid coolant is pumped through the one or more coolant circuits, through the immersion enclosure along the computing modules that are at least partially immersed therein, such that the cooling arrangement cools the computing modules by means of immersion cooling with the liquid coolant taking in the generated heat and guiding it away from the computing modules to the heat exchanger to be transferred to a heating medium that flows through the heating system of the greenhouse, other building or industrial process equipment to be heated.

Thus a truly flexible, super-efficient and economic energy optimisation method is obtained according to the invention. Large amounts of high-grade heat can now be generated by large numbers of at least partly immersed computing modules that are placed inside immersion enclosures that can be closely packed/stacked inside an easily transportable container, for example a standard size sea container Those large amounts of high-grade heat can subsequently efficiently be exchanged with a heating medium and transferred to whatever site of a greenhouse, other building or industrial process equipment to be heated where the mobile unit is placed, for example because at that site a heat demand is deemed largest, or an amount of available excess electricity is deemed largest. In contrast with a conventional data centre, the mobile unit is placed at a site of a greenhouse, other building or industrial process equipment to be heated, which shortens the distance between the greenhouse, other building or industrial process equipment and the mobile unit, further increasing the efficiency. This way, electricity, for example electricity from a CHP, may be converted into heat for heating a greenhouse, other building or industrial process equipment at higher efficiencies compared to the prior art, for example at 95% efficiency.

By having the liquid coolant, heat may be transferred from the computing modules to the liquid coolant by an increased amount of convection. Additionally, the liquid coolant may have a truly higher heat capacity than for example environmental air, such that a large amount of heat can be absorbed by the liquid coolant and transferred to the heating medium. For example, compared to the prior art, the heat transfer from the at least partially immersed computing modules towards the greenhouse or building may be up to 1500× higher due to the immersion cooling with the liquid coolant. The computing modules only need relatively small immersion cooling surfaces for the required immersion cooling to be sufficient. As a result, they need limited immersion spaces and large numbers of modules can be provided inside the mobile unit's container.

It has been found that in the prior art, the maximum heat transfer away from each of the computing modules, and subsequently also the transfer of heat with air into the building is limited, which may be further aggravated due to the uneven cooling of the computing modules. As a result, the number of computing modules inside a mobile data centre and the maximum operating power of the computing modules positioned in the container was relatively small, such that a large number of containers is required to generate sufficient heat for heating a building.

As a result of the advantageous aspects of the invention, a large amount heat may be transferred to the heating system of the greenhouse, other building or industrial process equipment, which may allow for proper heating of the greenhouse, other building or industrial process equipment with heat generated by the computing modules. Thereby, the method according to the present invention may offer several additional advantages:

Firstly, as a maximum heat transfer is relatively high, the computing modules may perform computing tasks at a well controllable temperature, without running a risk of getting overheated, and while generating high-capacity heat for efficiently heating the greenhouse, other building or industrial process equipment up to a desired temperature. The well controllable temperature of the computing modules helps to obtain an advantageous service life of the computing modules. Even during warm days, the entire mobile unit may run quiet, whereas the computing modules may be kept fully operational and keep on computing at maximum speeds without running said risk of getting overheated.

Secondly, the number of computing modules may be adapted with more flexibility. Compared to the prior art, a lower number of computing modules may be necessary for heating the greenhouse, other building or industrial process equipment. At the same time, larger numbers of computing modules may be arranged within the mobile unit compared to the prior art, while still being cooled sufficiently. As such, an amount of heat generated by, and an amount of electricity required by the mobile unit can be selected with great freedom by arranging/activating a selected number of computing modules in the immersion enclosure.

Thirdly, the temperature of the liquid coolant, for example oil, after having been pumped along the heat-generating immersed computing modules, may become relatively high, for example up to temperatures higher than 45° C. In particular, the temperature may be higher than 55° C., such as 65° C., which may then result in the heating medium of the heating system to be heated up to a relatively high temperature, for example up to temperatures higher than 55° C., such as 60° C., such that the greenhouse, other building or industrial process equipment may be heated by the mobile unit using the heating system. This may now be possible without modifications as large radiators/convectors as heating systems of greenhouses are typically designed for heating medium temperatures of 60° C.

Therewith, the method enables sustainable heating of a building or greenhouse. It has been found that even with a CHP as electricity source, CO₂-emissions for heating the greenhouse, other building or industrial process equipment may be reduced 40% compared to the prior art.

Further, the method may advantageously be applied to heat several industrial process equipment, for example, equipment applied in industrial processes in the food and beverage industry, dairy industry, drying processes, feedwater and steam processes and all other industrial processes requiring heating, especially when relatively high temperatures are required. These temperatures may now be achieved sustainably using sustainable heat, whereas in the past usually fossil heated was required to achieve sufficient temperatures.

The computing modules may be packed such closely that heat of more than 1 MW of heat may be generated by a single mobile unit, for example 2 MW. A size of 2 MW may be advantageous as this is a common power grid maximum in the Netherlands. However, other heating power amounts may also be possible.

The computing modules are at least partly immersed, and may typically be fully immersed. In particular, a top side of the computing modules can be arranged at least 2-5 cm below a fluid level of the liquid coolant for an advantageous flow of the liquid coolant along the computing modules. However, other configurations, such as immersion of only a cooling surface or direct-to-chip cooling, may also be possible.

As the cooling arrangement comprises the heat exchanger, the mobile unit is suited for heating the greenhouse, other building or industrial process equipment to be heated by means of its own dedicated heating medium, such as water, that can be different from the liquid coolant, for example oil. The heating medium may, after coupling the heat exchanger to the heating system, flow through an outer/heating side of the heat exchanger. The coolant may be pumped through an opposing inner/cooling side of the heat exchanger while exchanging the heat cooled from the computing modules between the coolant and the heating medium.

The outer/heating side of the heat exchanger may be connected to the heating system between a return conduit and a feeding conduit to heat heating medium flowing from the return conduit before entering the feeding conduit, for example via a manifold when multiple heat exchangers are provided.

The heat exchanger may exchange heat from a relatively high coolant temperature, for example 55° C.-65° C. The heat exchanger may cool the liquid coolant from the relatively high coolant temperature to a relatively low coolant temperature, for example 30° C.-50° C., such as 40° C. The heat exchanger may have an efficiency of at least 95%. The heating medium in the return conduit may, for example, have a temperature of at least 20° C. before flowing through the heat exchanger. The heat exchanger may heat the heating medium to a relatively high temperature, for example 54.5° C.-60° C. These ranges have been found to be especially advantageous for heating an existing heating system in various applications, for example in horticulture.

The unit is mobile and may be transported towards and then installed quickly and easily at a site of the greenhouse, other building or industrial process equipment to be heated. Additionally, the unit may be installed at a site of a greenhouse having a demand for electric heating at that moment. As the heat is generated locally by the computing modules inside the mobile unit's container, at the site of the greenhouse, other building or industrial process equipment to be heated, heat transmission losses may be kept to a minimum.

The electricity may be provided by a local electricity source, for example from solar panels or a windmill. Therewith, the mobile unit may provide a solution for using excess electricity when it is not possible or economic to feed excess electricity back into a utility grid.

The computing modules may include computers, servers or ASIC units, performing various computational tasks, such as scientific computational tasks, storage tasks or computational tasks related to blockchain applications.

As the liquid coolant circuits are closed-loop circuits, contact between the computing modules and external substances such as salts, acids or small particles can be limited and risk of deterioration or blockage of the at least partly immersed computing modules due to contact with external substances can easily be reduced.

By having the pump to pump the coolant through the coolant circuits no fans are required on the computing modules, such that the mobile unit is relatively silent and such that the number of moving parts in the coolant circuit, i.e. potential points of failure, is reduced.

In an embodiment, the method further may comprise the steps of placing an emergency cooler at the site of the greenhouse, other building or industrial process equipment to be heated, and coupling the emergency cooler to the heating system, wherein the heating system is a closed-loop heating circuit, and wherein that the emergency cooler is controllable to cool the heating medium before heat is transferred thereto in the heat exchanger. The emergency cooler is coupled to a return conduit of the heating circuit such that heat returned from the greenhouse, other building or industrial process equipment to be heated via the return conduit is removed from the heating medium.

The emergency cooler may be dimensioned to cool the heating medium to a temperature that is lower than a temperature of the liquid coolant, such that sufficient heat can be removed from the heating medium before reaching the heat exchanger. In particular, the emergency cooler may be dimensioned to cool the heating medium to at least 10° C., for example 15° C. below the temperature of the liquid coolant. It has been found that this cooling provides an advantageous balance between cooling of the computing modules and heating of the greenhouse, other building or industrial process equipment.

In addition thereto or in the alternative, the method further may comprise the steps of placing an emergency cooler at the site of the greenhouse, other building or industrial process equipment to be heated, and coupling the emergency cooler to the coolant circuit, wherein the emergency cooler is controllable to cool the liquid coolant before being pumped through the immersion enclosure, wherein the emergency cooler is coupled to a return conduit of the coolant circuit such that heat not transferred to the heating medium is removed from the liquid coolant.

By having an emergency cooler, computational tasks may also be performed with the computing modules when the generated heat cannot entirely be transferred to the greenhouse, other building or industrial process equipment to be heated. For example, when a temperature in the greenhouse, other building or industrial process equipment is already sufficient and no heating is required.

In an embodiment, the greenhouse, other building or industrial process equipment may be heated via a closed-loop heating circuit. This way, when the heat may not be transferred to the greenhouse, other building or industrial process equipment, heat may be transferred to the environment via the emergency cooler, such that the temperature of the computing modules can be better controlled.

In an embodiment, in addition to the return conduit of the heating system of the greenhouse, other building or industrial process equipment to be heated, the emergency cooler may be coupled to a feeding conduit of the heating system of the building or greenhouse to be heated via an emergency cooler mixing valve. This way, heat may be guided away from the computing modules, via the feeding conduit and the emergency cooler mixing valve towards the emergency cooler, without first being guided through the greenhouse, other building or industrial process equipment. This may be especially advantageous when the greenhouse, other building or industrial process equipment is already at a desired temperature, causing no heat to be required for heating the greenhouse, other building or industrial process equipment, for example during hot summer days.

In an embodiment having an emergency cooler, the method may comprise the steps of measuring a temperature signal representative for a return temperature of the heating medium returned via the return conduit of the heating system and/or representative for a return temperature of the liquid coolant returned via the return conduit of the coolant circuit before being pumped through the immersion enclosure and controlling the emergency cooler to be activated when the temperature signal exceeds a predetermined threshold value and/or to be deactivated when the temperature signal falls below a predetermined threshold value.

This way, a temperature in the return conduit may be controlled on the basis of the temperature signal by activating and/or deactivating the emergency cooler. As a result, a constant temperature or temperature range may be maintained in the return conduit and/or in the computing modules. This may be advantageous for a service life of the computing modules and/or for maintaining the greenhouse, other building or industrial process equipment to be heated at a constant temperature.

The temperature in the return conduit may be controlled to reach a target temperature of less than 45° C., for example a target temperature of 40° C. In particular, the threshold values may be selected to define a temperature bandwidth around the target temperature.

In addition or in the alternative to measuring a temperature of the return conduit, other temperatures may be measured, for example a temperature signal representative for a temperature of the computing modules.

In an embodiment having an emergency cooler, the emergency cooler may comprise a ground-coupled heat exchanger, wherein the ground-coupled heat exchanger is arranged to cool the heating medium before heat is transferred thereto in the heat exchanger, by capturing heat from the heating medium and dissipating heat in the ground.

This way, very sustainable cooling may be achieved with the ground-coupled heat exchanger wherein the heat removed from the heating medium is stored in the ground for later use.

In an additional or alternative embodiment having an emergency cooler, the emergency cooler may comprise at least one heat pump having an evaporator and a condenser wherein the evaporator is arranged to cool the heating medium before heat is transferred thereto in the heat exchanger. The evaporator may for example be arranged in or along the return conduit of the heating circuit.

As such, very sustainable cooling may be achieved with the at least one heat pump wherein the heat removed from the heating medium heats the condenser and can be used for heating therewith.

In a further embodiment, the step of coupling the heat exchanger of each of the one or more coolant circuits to the heating system of the greenhouse, other building or industrial process equipment to be heated may comprise the step of coupling the heat exchanger in series with the ground-coupled heat exchanger and/or arranging the condenser in or along the feeding conduit, such that, during the step of performing computing tasks with the computing modules, heat is transferred to the heating medium by the heat exchanger, and subsequently by the ground-coupled heat exchanger and/or by the condenser to upgrade a temperature of the heating medium before flowing through the heating system of the greenhouse, other building or industrial process equipment to be heated.

This way, the heating medium first flows through the heat exchanger and subsequently through the ground-coupled heat exchanger and/or along the condenser before reaching the greenhouse, other building or industrial process equipment, such that the ground-coupled heat exchanger and/or the at least one heat pump may advantageously be used both for cooling the heating medium in the return conduit and for heating the heating medium in the feeding conduit.

In an embodiment, the electricity source may comprise a combined heat-power generator (CHP) located on the site of the greenhouse, other building or industrial process equipment to be heated, in particular a fuel-driven CHP, such that the mobile unit is powered with electricity generated by the combined heat- and power generator, and such that the heating medium is partly heated by heat generated by the combined heat- and power generator. As the mobile unit is coupled to the heating system, the heating medium may be heated by the mobile unit, and also by the CHP. A maximum obtainable temperature of the heating medium of the CHP may be higher than that of the mobile unit, such that a temperature of the heating medium can be upgraded.

This way, a CHP can be used in a more optimised manner during a demand for heat and CO2, since the computing modules can be powered with any excess electricity of the CHP to perform computing tasks, while at a same time generating high grade heat that can also be used for heating the greenhouse, other building or industrial process equipment to be heated. As such, the electricity provided by the heat-power generator and electricity usage of the mobile unit may be adapted to match with each other such that energy usage is optimised. Compared to heating with only a CHP and/or a conventional boiler, such as a gas boiler, a significant decrease in fossil fuel use can be obtained of up to 60% by using the mobile unit according to the invention. In particular, the energy from the fuel that is converted into electricity is also converted into heat, such that a high fuel-to-heating system efficiency can be obtained, for example 95%.

The CHP may be a powered by natural gas, landfill gas, sewage sludge digestion gas or biogas. This way, heating may be performed even more sustainable. The CHP may have a rated electric power substantially equal to a maximum power consumed by the computing modules.

Use of electricity from the power grid may be too expensive to use for heating a greenhouse, other building or industrial process equipment due to tax reasons, especially in the Netherlands. In practice, this causes a difficulty in heating the greenhouse, other building or industrial process equipment without a boiler. By having a CHP as electricity source for the mobile unit, sustainable heating may become very economic.

Additionally, by having the local electricity source that may already be present at the site, such as the CHP, losses between the electricity source and the mobile unit may be relatively low.

The electricity source may be the CHP. Conventionally, a CHP is only used when electricity prices are relatively high compared to CHP fuel prices. As a result, at times when it is not possible to use the electricity generated by the CHP locally and when the generated electricity cannot be fed back into the public utility grid, the CHP is switched off. This usually results in a low utilisation rate of the CHP.

By having a CHP as electricity source, the mobile unit according to the present invention provides a meaningful and sustainable use of the electricity generated by the CHP to generate heat. Therewith, is now becomes possible to use the CHP continuously, even when electricity prices are relatively low compared to CHP fuel prices. As such, in this embodiment, the mobile unit increases utilisation rate of the CHP. The CHP may now efficiently provide generated electricity to the mobile unit, and run a relatively large part of the day, for example at least 12 hours or at least 18 hours, in particular continuously.

The electricity source may comprise multiple selectable sources, such as a public utility grid and a CHP. The selectable sources may be electrically coupled to the electric connector by a controller configured to select one or more of the selectable sources as electricity source and to electrically couple the electricity source to the electric connector. This way, an advantageous selection of an available electricity source can be made, for example depending on an instantaneous heat required for heating, energy prices or sustainable criteria

Additionally or alternatively, the method may comprise the step of providing an additional heat source, such as a solar collector, electric boiler, heat pump or geothermal source, wherein the step of coupling the heat exchanger of each of the one or more coolant circuits to a heating system of the greenhouse, other building or industrial process equipment to be heated via the additional heat source, such that the heating medium is partly heated by heat generated by the additional heat source. The additional heat source may comprise a CHP, for example the CHP that is comprised in the electricity source.

A CHP is conventionally used to heat the heating medium to a high temperature of up to 90-95° C. in order to generate as much heat as possible during the relatively short switch-on time. Due to the high heating medium temperature, the heat losses are correspondingly high.

By having the mobile unit and a CHP providing heat to the heating system during a relatively large part of the day, for example continuously, the heating medium can be heated to a lower temperature by the CHP, as heating is provided more continuously. The heating medium may for example be heated by the CHP to a temperature lower than 90° C., for example lower than 85° C. or to a temperature that is actually required for the heating system.

The additional heat source may, for example, be coupled with the respective heat exchangers in series and/or via mixing valves.

As the mobile unit is coupled to the heating system, the heating medium may be heated by the mobile unit, and also by the additional heat source. A maximum obtainable temperature of the heating medium of the additional heat source may be higher than that of the mobile unit, such that a temperature of the heating medium can be upgraded.

In a further embodiment, the step of coupling the heat exchanger of each of the one or more coolant circuits to the heating system of the greenhouse, other building or industrial process equipment to be heated may comprise the step of coupling the heat exchanger with the additional heat source in series, such that, during the step of performing computing tasks with the computing modules, heat is transferred to the heating medium by the heat exchanger, and subsequently by the additional heat source to upgrade a temperature of the heating medium before flowing through the heating system of the greenhouse, other building or industrial process equipment to be heated. The heat exchanger may be coupled in series with a high-temperature conduit of the additional heat source, such that, at least partially, the heating medium first flows through the heat exchanger and subsequently through the high-temperature conduit of the additional heat source before reaching the greenhouse, other building or industrial process equipment. The additional heat source may be a CHP.

In series, the additional heat source may further upgrade a temperature of the heating medium, for example upgrade to 70-95° C. A higher temperature may be particularly advantageous in case of high-temperature heating systems, for example in heating systems comprising a high-temperature storage system, such as a heating medium buffer tank.

The method may comprise a step of allowing a heating medium buffer tank of the heating system to cool to a temperature below 90° C., for example below 85° C. or to a temperature that is actually required for the heating system. Conventionally, heating medium buffer tank store heating medium at a high temperature of 90° C. or more, especially in horticulture, as energy prices, in particular fossil fuel prices for heating, and weather conditions may vary. It has been found that according to the present invention, sufficient heating of the heating system may now be ensured at lower temperatures of the heating medium buffer tank, as the mobile unit may provide a relatively reliable and stable heating source.

In addition, the step of coupling the heat exchanger with the additional heat source in series may comprise providing a mixing valve and coupling the heat exchanger with the additional heat source via the mixing valve. The method may further comprise a step of regulating a heating medium temperature with the mixing valve.

As the heating medium may be heated up to a relatively high temperature with the immersion cooled computing modules of the mobile unit, further heating with the additional heat source in series under some circumstances may not always be necessary. The mixing valve then makes it possible to mix the heated heating medium coming from the heat exchanger of the mobile unit in a bigger or lesser amount with colder heating medium that flows back from the greenhouse, other building or industrial process equipment to be heated, and/or with colder heating medium cooled by an emergency cooler, such that a temperature thereof may be regulated before the heating medium flows through the additional heat source.

In an embodiment, the method may further comprise the steps of: before the step of performing computing tasks with the computing modules, determining an expected heat required for heating the greenhouse, other building or industrial process equipment to be heated; determining a number of the computing modules to be provided based on the expected heat required and an expected heat generation of each computing module and arranging the determined number of computing modules in the immersion enclosure in the one or more coolant circuits in the mobile unit.

As a result of the modular construction of the mobile unit having one or more coolant circuits with a heat exchanger a pump and an immersion enclosure, the mobile unit may be adapted to the greenhouse or building relatively easy by increasing and/or decreasing a number of computing modules in an immersion enclosure and/or by increasing and/or decreasing a number of coolant circuits.

Thus, in contrast with the prior art, the number of computing modules is determined in dependence of an expected heating input required for the building, instead of other factors, such as a required computational power and/or a size of the mobile unit. This way, computational power is varied to meet a heating demand, which is a fundamentally different approach from aiming to fully use the available computational power as in the prior art. The expected heat may be an expected average heat required in the heating system during a particular season, a percentage of an expected maximum heat required, or another expected heat for the respective heating system.

Therewith, a heat output of the mobile unit may advantageously be adjusted, to be specifically tailored to a heat requirement of the greenhouse, other building or industrial process equipment.

The number of computing modules may be determined in further dependence of a heat output of an additional heat source. In embodiments where the electricity source comprises a combined heat-power generator (CHP), and wherein the CHP is an additional heat source, the number of computing modules may be determined in further dependence of a heat- and electricity output of the CHP.

The mobile unit may comprise a controller operatively connected to the computing modules, wherein the controller is configured to determine a heat required for heating the heating the greenhouse, other building or industrial process equipment, and configured to control the computing modules in dependence of the determined required heat. Control may for example be performed by increasing and/or decreasing a computation speed of the computing modules and/or by activation and/or deactivating computing modules. This way, a heating output of the mobile container may be varied.

In an embodiment, the method further comprises the steps of determining a heat required for heating the greenhouse, other building or industrial process equipment; and controlling the computing modules in dependence of determined required heat.

As a result of, for example, weather or use, a required heat may vary with time and therefore not be equal to an expected heat required for heating. By controlling the computing modules, heat generated therewith may be controlled.

The determined required heat may be an instantaneous heat required at that specific moment in time, or a heat that is required according to a prediction of an upcoming time period, for example an upcoming time period of several minutes, hours and/or days. The determined required heat may be heat flow or power, or alternatively be a setting or control input for the computing modules.

The mobile unit or the heating system may comprise a temperature sensor configured to measure a temperature signal. The controller may be operatively connected to the temperature sensor to determine the required heat.

Additionally or alternatively, the controller may be configured to receive external data representative for a required heat of heating system to determine the required heat. The external data may comprise a temperature, required heating power or outside temperature. The controller may for example be provided with a wired or wireless internet connection.

The controller may be configured to control the computing modules in dependence of the temperature signal and/or the received external data.

The temperature sensor may be arranged to measure a temperature sensor representative for a temperature of the heating medium. For example, the temperature sensor may be arranged, in flow direction of the heating medium, before the heat exchanger, for example in a return conduit of the heating system. Additionally or alternatively, the temperature sensor may be arranged, in the flow direction of the heating medium, after the heat exchanger, for example in a feeding conduit of the heating system.

Additionally or alternatively, the temperature sensor may be arranged to measure a temperature signal representative for a temperature of the liquid coolant. The temperature sensor may be arranged in the coolant circuit, for example, before or after being pumped along the computing modules.

Multiple temperature sensors may be provided in multiple positions and on multiple conduits.

As the computing modules may be controlled relatively quickly, the mobile unit may respond relatively fast to a varying heating demand of the greenhouse, other building or industrial process equipment.

The controller may be configured to control the heating modules to provide the determined required heat, while reducing cost, CO₂ produced and/or gas usage. As such, the mobile unit allows for further energy optimisation.

In an embodiment, the method comprises the step of balancing a voltage and/or frequency of the electricity source. The electricity source may comprise a power grid, such as a public utility grid. Especially due to an increasing amount of sustainable energy on the public utility grid, voltage and frequency of the energy supply may vary increasingly, for example due to varying solar and/or wind. The variation in the power grid is further aggravated by the reduction in relatively stable and adjustable fossil-fuel fired power plants on the power grid.

Further, solutions for temporary energy storage exist, for example by means of batteries or hydrogen. However, temporary energy storage has been found to be relatively expensive compared to balancing the mobile unit.

The mobile unit may advantageously be used to balance the electricity source, i.e. to influence the voltage and/or frequency of the electricity source by adjusting the electricity consumed by the computing modules. This way, the electricity source may be balanced by controlling the electricity consumed by the computing modules alleviating a need for temporary energy storage.

In an embodiment, the method may comprise the step of determining a balancing demand of the electricity source and controlling the computing modules in dependence of the determined balancing demand.

The balancing demand may be represented by a deviation in a voltage and/or a frequency of the electricity source from desired values. The desired voltage of the electricity source may for example be 400V or 480V, and a deviation therefrom may represent a balancing demand. Similarly, a desired frequency of the electricity source may be 50 Hz or 60 Hz.

The controller may be configured to detect increases and decreases in an electricity signal representative for the balancing demand. The controller may be operatively connected to a sensor configured to measure the electricity signal representative for the balancing demand. The electricity signal may represent a voltage and/or a frequency of the electricity source. Additionally or alternatively, the controller may be configured to receive external data representative for the balancing demand, such as electricity prices, weather data, voltage and/or frequency of the power grid, etc. The controller may for example be provided with a wired or wireless internet connection.

The controller may be configured to control the computing modules in dependence of the electricity signal and/or the received external data.

As the computing modules may be controlled relatively quickly, the mobile unit may provide an advantageous benefit by balancing the electricity source. For example, the electricity, i.e. power, consumed by the computation modules may be adjusted within 15 minutes, for example even within seconds.

The advantageous aspect of balancing a voltage and/or a frequency of the electricity source may also be beneficial in different applications, for example in methods or mobile units lacking the characterising features of the present invention, such as where the cooling arrangement is not connected to a greenhouse, other building or industrial process equipment to be heated.

Especially in embodiments where the electricity source comprises a CHP and a power grid: relatively large balancing of the electricity source may be performed: by activation of the CHP, and deactivation of the computing modules, electricity may be generated by the CHP and fed into the power grid, whereas, by deactivation of the CHP and activation of the computing modules, electricity may be taken from the grid. This way, an advantageous combination of positive and negative balancing, for example up to 2 MW, may be performed, which is unseen in the prior art.

The controller may be operatively connected to the CHP and be configured to control the CHP to adjust heat and electricity produced thereby. The CHP may be configured to adjust heat and electricity produced in response to a control from the controller, for example by closing a fuel supply valve and/or reducing a rotation speed.

In an embodiment, wherein the electricity source comprises a CHP connected to a power grid, the method may comprise the step of, upon detection of a decrease in voltage and/or frequency of the power grid, reducing a power generated by the CHP, while remaining the computing modules in operation. This way, heat may still be generated relatively sustainably. The computing modules may then be controlled to decrease their consumed power upon detection of a further decrease in voltage and/or frequency of the power grid.

In an embodiment, wherein the electricity source comprises a CHP connected to a power grid, the method may comprise the step of, upon detection of an increase in voltage and/or frequency of the power grid, reducing a power generated by the CHP and/or controlling the computing modules to increase their consumed power

The controller may be configured to select a combination of electricity generation by the CHP and electricity usage by the computing modules that approaches the balancing demand, but reduces cost, CO₂ produced and/or gas usage, for example to select the combination that also provides the required heat. As such, the mobile unit allows for even further energy optimisation.

The controller may be configured to control the computing modules continuously and/or periodically, for example every 1-15 minutes, such as every 1-3 minutes. This way, a fast response to a varying heating requirement and/or electricity source imbalance maybe provided.

The controller may be configured to compare the temperature signal, the electricity signal and/or the received external data with a threshold value. Also multiple threshold values and/or more advanced control configurations may be used. The controller may for example comprise P, PI or PID control, linear-quadratic regulation, model-predictive control, or other types of control.

In particular, control may be performed such that a temperature of 55-60° C. is maintained in the heating system. Additionally or alternatively, control may be performed such that a voltage, for example 400V or 480V, and/or a frequency, for example 50 Hz or 60 Hz, is maintained in the power grid.

The controller may be configured to increase or decrease a power consumption of the computing modules by, respectively, increasing or decreasing the clock speed and/or hash rate of the computing modules.

The computing modules may have a rated power, for example 3.5 kW. The rated power may be a consumed electric power, at a rated CPU clock speed and/or rated hashing rate. The rated power, the rated CPU clock speed and/or the rated hashing rate may be specified by the manufacturer of the computing modules. The rated power may be a power consumption for which the computing modules are designed by the manufacturer. The rated power may be the power at which the computing modules operate most efficiently, i.e. wherein the amount of computations per watt is relatively high.

The computing modules may configured to be controlled by the controller to adjust their power to less than the rated power, for example in a range between 0-3.5 kW or 2-3.5 kW.

The computing modules may be configured to be controlled by the controller to adjust their power consumption above the rated power, for example at least 25% above their rated power, such as at least 50% above, for example at least 75% above their rated power. The computing modules may for example be configured to adjust their power consumption between 3.5-7 kW. The computing modules may for example be overclocked to operate above a rated clock speed or above a rated hashing rate.

The computing modules may be configured to adjust their power consumption below and above their rated power, for example 0-7 kW, such as 2-7 kW.

By controlling the computing modules beyond their rated power, a large amount of heat may be transferred from the computing modules. Further, also a large amount of electricity may be consumed by the computing modules.

The method may comprise the step of, optionally, removing a power supply unit from the computing modules, and electrically coupling a heavy-load power supply unit to the electric connector and to the computing modules. The heavy-load power supply unit may be electrically coupled to one or multiple computing modules. Heavy-load may be understood as having a higher power than a power supply unit conventionally available on the computing module. The heavy-load power supply unit may, per computing module, have a power supply capacity of at least 1.5 times the rated power of the respective computing module, for example at least twice the rated power of the respective computing module.

Computing output, that is the amount of computations that can be performed, does not scale linearly with consumed power of a computing module. In a datacentre, computing modules are operated around their rated power, or at a power at which their efficiency is relatively high.

Normally, the skilled worker would be hesitant to operate computing modules at a power that has a large deviates from the rated power as this would reduce efficiency, i.e. computations per Watt of electric power consumed. However, it has been found that due to the efficient and sustainable heat transfer from the computing modules towards the heating system, the computing modules may advantageously be operated relatively far above their rated power, even at twice their rated power. This way, computations may be performed at a higher speed then in the past, while sustainable heating is provided to the heating system.

In addition and/or alternative to controlling the computing modules, the controller may be configured to control other devices, such as the pump, the heating exchanger, an emergency cooler and/or valves, such as a valve to an additional heating source or emergency cooler.

In an embodiment, the method may further comprise the steps of removing the mobile unit from the site of the greenhouse, other building or industrial process equipment by disconnecting the electric connector from the electricity source, decoupling the cooling arrangement from the greenhouse, other building or industrial process equipment to be heated and providing the mobile unit at a site of another greenhouse, other building or industrial process equipment to be heated.

Thanks to the advantageous mobile unit, the mobile unit may, for example be moved preceding or during a period in which a surplus of heat is expected in a first greenhouse or building, while a shortage of heat is expected in a second greenhouse or building in that period. This may for example be the case when crops grown in the first greenhouse differ from crops in the second greenhouse.

The invention also relates to a mobile unit according to the present invention. The mobile unit provides advantages similar to the advantages of the method, as described above.

In an embodiment, the mobile unit may comprise multiple coolant circuits. The heat exchangers of each of the coolant circuits can then be fluidly connected to each other to be couplable to the greenhouse, other building or industrial process equipment to be heated, for example in parallel and/or the respective immersion enclosures of the coolant circuits can then be positioned above each other and/or side-by-side and/or in rows in the mobile unit.

By having multiple coolant circuits, redundancy may be provided, and, especially when arranged in parallel, above, side-by-side and/or in rows in the mobile unit, maintenance may be performed easier, for example by deactivating only one of the multiple coolant circuits. Furthermore, additional heating capacity and/or computation capacity may be installed relatively easy by providing a pump, heat exchanger and an immersion enclosure with computing modules in the mobile unit, filling the coolant circuit with liquid coolant, and coupling the respective coolant circuit to the greenhouse, for example via a main distribution manifold.

In particular when the heat exchangers of the respective coolant circuits are coupled to the greenhouse, other building or industrial process equipment with their outer/heating sides connected in parallel, temperatures of the heating medium on the outer/heating side of the heat exchangers may be similar for each heat exchanger. Therewith, an inner/cooling side of the respective heat exchangers may be similar, and a temperature of the computing modules in the liquid coolant may also be similar, such that this temperature can be controlled very well in each of the coolant circuits.

Furthermore, when the heat exchangers are connected with their outer/heating sides connected in parallel, a new coolant circuit may be added by coupling an outer/heating side of the respective heat exchanger in parallel to the return conduit of the heating system. This way, a new coolant circuit may even be added to the mobile unit when computational tasks are being performed with computing modules in one or multiple other coolant circuits.

In a further embodiment, a number of computing modules that gets at least partially immersed in each of the immersion enclosures may be kept substantially the same. As such, temperatures on the respective inner/cooling sides of their heat exchangers may be approximately the same. Therewith, controllability of the temperature of a return conduit and/or of the computing modules may be improved.

In an embodiment, immersion enclosures of the coolant circuits are positioned in at least two rows in the mobile unit, wherein the mobile unit comprises an entrance, and a walking space that extends in the mobile unit from the entrance between the at least two rows of immersion enclosures. This way, computing modules may be arranged in the immersion enclosure, the immersion enclosure may be filled with liquid coolant and/or maintenance may efficiently be performed from the walking space.

It has been found that the computing modules may be positioned relatively closely such that at least 100 computing modules may be arranged in a mobile unit, such as at least 200. For example, a heat output of at least 1 MW may be generated by a single mobile unit, for example 2 MW.

The immersion enclosures may be positioned on top of each other. For example, two layers of immersion enclosures may be provided on top of each other in the mobile unit. This way, a relatively large amount of computing modules may be provided in the mobile unit, such that a large amount of heat may be generated by a single container. As such, the heat output of a single mobile unit may be increased further, for example to 2 MW by a single mobile unit having the size of a standard sea container such as a 45 ft shipping container. In a further embodiment, the respective heat exchangers and/or the respective pumps of the coolant circuits are positioned in the mobile unit substantially in line with the at least two rows. A clear visual overview may provide additional efficiency benefits during maintained and/or addition or removal of coolant circuits.

Further preferred embodiments of the method and mobile unit are described herein.

The present invention further entails an assembly for energy optimisation between a mobile unit with computing modules and a greenhouse, other building or industrial process equipment to be heated, the use of the assembly for energy optimisation between computing modules and a greenhouse, other building or industrial process equipment to be heated, the use of a mobile unit according to one of the embodiments disclosed herein for balancing the electricity source, and the use of the assembly according to any of the embodiments disclosed herein for balancing the electricity source.

### BRIEF DESCRIPTION OF THE DRAWINGS

Further characteristics and advantages of the invention will now be elucidated by a description of embodiments of the invention, with reference to the accompanying drawings, in which:

FIG. 1 schematically depicts an assembly for energy optimisation between a mobile unit with computing modules and a greenhouse, other building or industrial process equipment to be heated, comprising the mobile unit according to an embodiment of the invention;

FIG. 2 schematically depicts a perspective view of a partially opened mobile unit according to an embodiment of the invention; and

FIG. 3 schematically depicts a side view, in perspective, of the partially opened mobile unit of FIG. 2.

Throughout the figures, the same reference numerals are used to refer to corresponding components or to components that have a corresponding function.

### DETAILED DESCRIPTION OF EMBODIMENTS

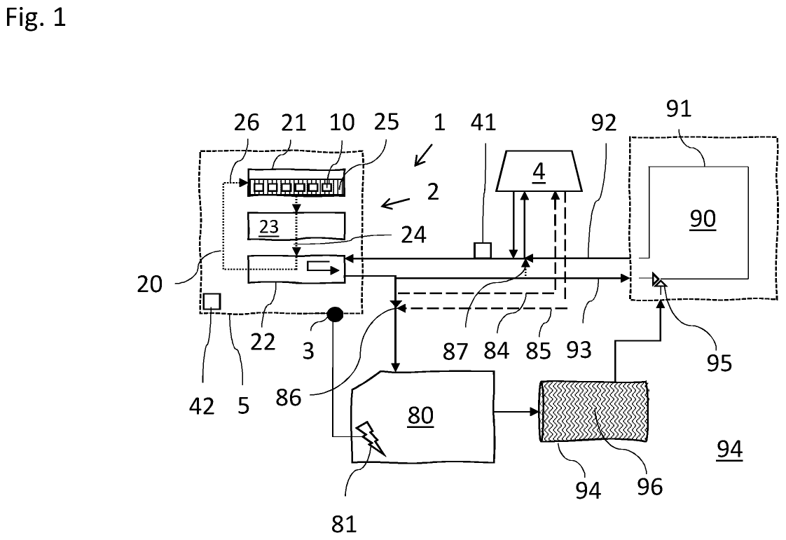

FIG. 1 schematically depicts an assembly for energy optimisation between a mobile unit 1 with computing modules 10 and a greenhouse 90 to be heated. The mobile unit 1 comprises a transportation container 5, in particular a standard size sea container, wherein multiple computing modules 10 are arranged to perform computing tasks whereby heat is generated.

The mobile unit 1 comprises a cooling arrangement 2 arranged in the transportation container 5 and couplable to the greenhouse, other building or industrial process equipment 90 to cool the computing modules 10 and to guide heat away from the computing modules 10 towards the greenhouse 90.

The cooling arrangement 2 comprises a closed-loop coolant circuit 20 that comprises an immersion enclosure 21 filled with a liquid coolant 25, a heat exchanger 22 (for exchanging heat between the coolant circuit 20 and a heating system 91 of the greenhouse, other building or industrial process equipment to be heated), and a pump 23 (for pumping liquid coolant 25 through the closed-loop coolant circuit 20). After passing the heat exchanger 22, the coolant is pumped to the immersion closure 21 via a return conduit 26.

The computing modules 10 are arranged in the immersion enclosure 21 of the coolant circuit 20 to be immersed in the liquid coolant 25 to be cooled via immersion cooling. The computing modules 10 here are arranged next to each other in one horizontal plane to be fully immersed in the liquid coolant 25, wherein a top side of the computing modules 10 is 4 cm below a fluid level of the liquid coolant 25 in the immersion enclosure 21.

The cooling arrangement 2 is couplable to the heating system 91 of the greenhouse 90 via the heat exchanger 22. The heating system 91, when coupled with the heat exchanger 22 of the at least one cooling circuit 20 forms a closed loop with a return conduit 92 and a feeding conduit 93. The heating system 91 comprises a high-temperature storage system, in particular heating medium buffer tank 94 configured to store heating medium 96 at a high temperature. The buffer tank is maintained at a temperature below 90° C.

Via a first mixing valve 95 of the heating system 91, heating media flowing from the heating medium buffer tank 94 and from the mobile unit 1 may be mixed to obtain a desired temperature in the greenhouse 90.

The heat exchanger 22 here is of the fluid-fluid type to exchange heat between the liquid coolant 25 and the liquid heating medium 96. The heating medium 96, here water, is different from the liquid coolant 25, here a dielectric liquid, in particular oil.

The pump 23 of the coolant circuit 20 is configured to, when computing tasks are performed with the computing modules 10, pump the liquid coolant 25 through the coolant circuit 20, including through the immersion enclosure 22 along the computing modules 10 that are immersed therein.

This way, the cooling arrangement 2 cools the computing modules 10 by means of immersion cooling with the liquid coolant 25 taking in the generated heat and guiding it away from the computing modules 10 to the heat exchanger 22 where it is transferred to the heating medium 96 that flows through the heating system 91 of the greenhouse 90.

Therewith, when computing tasks with the computing modules 10 the liquid coolant 25 may reach a temperature of 65° C. and the heating medium 96 reaches a temperature of 60° C.

The heat exchanger 22 cools the liquid coolant to a relatively low coolant temperature of 40° C. The heating medium in the return conduit 92 has a temperature of at least 20° C. before flowing through the heat exchanger 22.

The assembly comprises an emergency cooler 4 arranged on the site of the greenhouse 90 that is coupled to the heating system 91. The emergency cooler 4 is configured to be controlled to, in use, whenever deemed necessary, cool the heating medium 96 flowing through the heating system 91, before heat is transferred into that heating medium 96 in the heat exchanger 22. The emergency cooler 4 is coupled to the return conduit 92 of the heating system 91, such that, in use, any excess heat returned from the greenhouse 90 via the return conduit 92 is removed from the heating medium 96 by the emergency cooler 4.

Additionally, the emergency cooler 4 is coupled to the feeding conduit 93 of the heating system 91 via an emergency cooler mixing valve 87. This way, a part or all of the heating medium 96 flowing away from the heat exchanger 22 may bypass the greenhouse 90 via the emergency cooler mixing valve 87 towards the emergency cooler 4 when no heat is required to heat the greenhouse 90, but when heat is generated by the computing modules 10.

The emergency cooler 4 is dimensioned to cool the heating medium 96 to 15° C. below the temperature of the liquid coolant 25.

The mobile unit 1 comprises an electric connector 3 that connects with an electricity source 81 for powering the pump 23 and the computing modules 10 of the mobile unit 1. The electricity source 81 is a fuel-driven combined heat-power generator (CHP) 80 located on the site of the greenhouse 90.

The heat exchanger 22 of the coolant circuit 20 is coupled with the heating system 90 and is also coupled with the CHP 80. The CHP 80 is connected branched off from feeding conduit 93, such that, in use, the heating medium 96 can first be heated by the mobile unit 1, and if necessary, then can get upgraded in temperature by the CHP 80. The CHP 80 has a rated electric power substantially equal to a maximum power consumed by the computing modules.

In use, heat coming from the computing modules is transferred to the coolant 25 and then into the heating medium 96 by the heat exchanger 22. Subsequently the heating medium 96 can be guided along the CHP 80, such that the heating medium 96 then gets heated by the CHP 80 to upgrade a temperature of the heating medium 96 before flowing through the heating system 91 of the greenhouse 90, for example upgrade to 70-95° C.

A second mixing valve 86 is provided and the heat exchanger 22 is coupled with the CHP 80 via this mixing valve 86. The second mixing valve 86 is configured to mix the heated heating medium 96 coming from the heat exchanger 22 with colder heating medium 96 cooled by the emergency cooler 4, such that a temperature of the heating medium 96 before flowing through a high-temperature conduit in the CHP 80 may be regulated with the mixing valve 86. Additionally or alternatively, the mixing valve 86 may be configured to mix with colder heating medium 96 that flows back from the greenhouse 90 via the return conduit 92.

The mobile unit 1 comprises a temperature sensor 41 to measure a temperature signal representative for a return temperature of the heating medium 96 returned via the return conduit 92 of the heating system 91. The temperature sensor 41 is arranged on the return conduit 92.

Furthermore, a controller 42 is provided to control the emergency cooler 4 to be activated when the temperature signal exceeds a predetermined threshold value and/or to be deactivated when the temperature signal falls below a predetermined threshold value. This way, the temperature of the heating medium 96 in the return conduit 92 is controlled to reach a target temperature of 40° C. The controller 42 may also be configured to control other components of the assembly.

The controller 42 is operatively connected to the temperature sensor 41, to the CHP 80 and to computing modules 10, and is configured to determine a heat required on the basis of the temperature signal, for heating the heating the greenhouse, other building or industrial process equipment, and configured to control the computing modules 10 in dependence of the determined required heat.

The controller 42 is connected via a wireless internet connection to an external data source and receives weather data, electricity prices and a voltage and frequency of the power grid and is operatively connected to a sensor measuring the voltage and frequency provided by the CHP. The controller 42 is configured to control the computing modules 10 by sending an instruction to the computing modules 10 to increase or decrease a computation speed, to activate (start performing computations) or to deactivate (stop performing computations).

In use, the controller 42 detects increases and decreases in the voltage and frequency of the power grid, and quickly controls the computing modules to respond to the detected increases and decreases within 15 minutes, for example within seconds. If a decrease in voltage of the power grid is detected, the controller sends a command to the CHP to reduce heat and electricity produced thereby, for example by closing a fuel supply valve and/or reducing a rotation speed of the CHP. Upon detection of a further decrease, electricity consumed by the computing modules 10 is reduced.

The controller is configured to continuously select a combination of electricity generation by the CHP and electricity usage by the computing modules 10 that provides sufficient heat for heating the greenhouse, other building or industrial process equipment, while minimising CO₂ produced by the CHP.

In other embodiments, wherein electricity source also comprise a public utility grid, the controller may be configured to determine balancing demand of the electricity source and controlling the computing modules in dependence of the determined balancing demand. The controller may be configured to receive an electricity signal representative for a voltage and/or a frequency of the public utility grid, and adjust the computing modules 10 and/or the CHP 80 in response to a balancing demand, for example when the electricity signal represents a different voltage and/or frequency than 400V, 50 Hz. The controller 42, in use of such embodiments, selects a combination of electricity generation by the CHP 80 and electricity consumption by the computing modules 10 that meets the balancing demand, but reduces costs and CO₂. and adjusts, e.g. activates, increases power, decreases power, or deactivate the computing modules 10 and the CHP 80 accordingly.

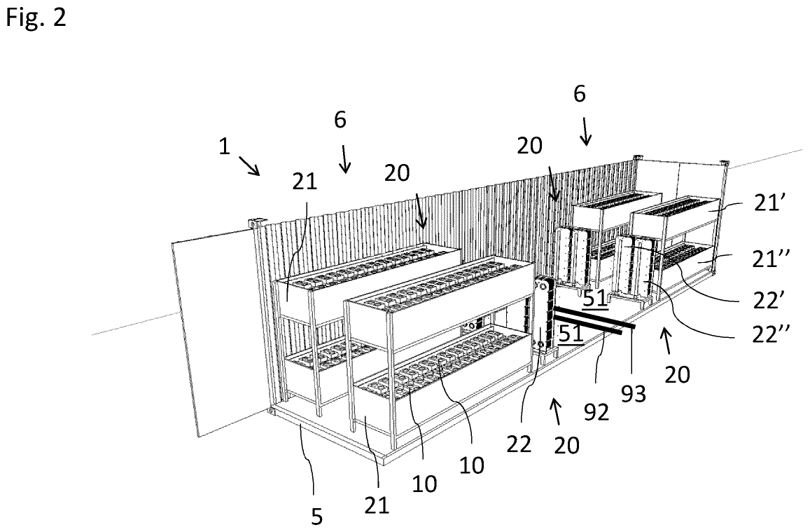

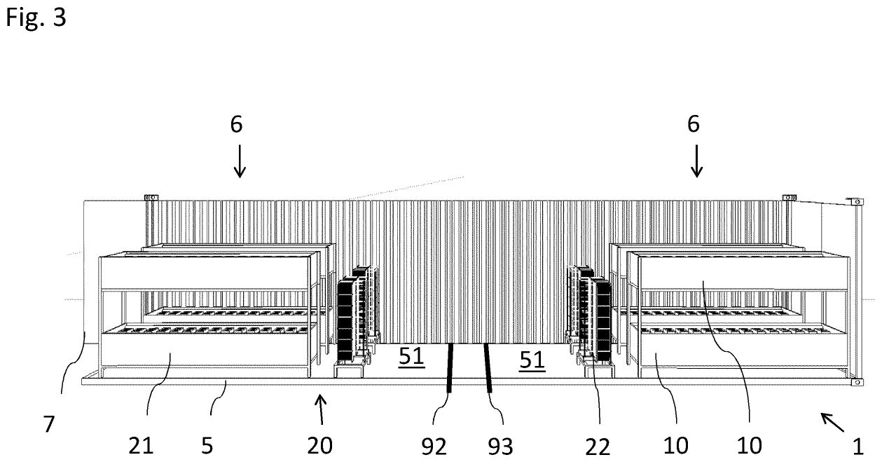

FIGS. 2 and 3 schematically depict perspective views of a partially opened mobile unit 1 according to an embodiment of the invention. The mobile unit 1 here comprises multiple coolant circuits 20, arranged in a shipping container 5. Each coolant circuit 20 comprises an immersion enclosure 21′ 21″, fluidly connected to a pump and a respective heat exchanger 22′ 22″. The outer/heated sides of the heat exchangers 21 of each of the coolant circuits 20 are fluidly connected (not shown) to each other to be couplable to the greenhouse, other building or industrial process equipment, via the return conduit 92 and the feeding conduit 93.

The number of computing modules 10 in each of the immersion enclosures 21 here is the same, such that an amount of heat generated in each coolant circuit 20 is substantially the same.

The respective immersion enclosures 21 of the coolant circuits 20 are positioned above each other and side-by-side and in two rows 6 in the mobile unit 1. The respective heat exchangers 22 and the respective pumps (not shown) of the coolant circuits 20 are positioned in the mobile unit 1 substantially in line with the two rows 6. The immersion enclosures 21 may also be positioned on top of each other, for example in two layers of immersion enclosures 21 on top of each other.

The mobile unit 1 comprises an entrance 7 and a walking space 51 that extends in the mobile unit 1 from the entrance 7 between the two rows 6 of immersion enclosures 21.

The computing modules 10 have a rated power of 3.5 kW specified by the manufacturer, but are configured to be controlled by the controller to adjust their power consumption above the rated power by overclocking. The computing modules may adjust their power between 2-7 kW by increasing or decreasing their hash rate. Before being arranged in the immersion enclosures 21, the power supply unit of the computing modules 10 have been removed, and a heavy-load power supply having a power supply capacity of at least twice the rated power is electrically coupled to the respective computing modules 10 and the electric connector to supply the computing modules with sufficient electricity above the rated power.

The mobile unit 1 is a standard sized 45 ft shipping container, the computing modules are packed such that a heat of 2 MW may be generated by the mobile unit.

Besides the shown and described embodiments, numerous variants are possible. For example the dimensions and shapes of the various parts can be altered. Also it is possible to make combinations between advantageous aspects of the shown embodiments.

The emergency cooler 4 may, for example, comprise a ground-coupled heat exchanger arranged to cool the heating medium 96 before heat is transferred to the heating medium 96 in the heat exchanger 22. Additionally or alternatively, the emergency cooler 4 may comprise at least one heat pump having an evaporator arranged to cool the heating medium 96 before heat is transferred to the heating medium 96 in the heat exchanger 22. In a further embodiment, the heat exchanger 22 may be coupled in series with the ground-coupled heat exchanger and/or a condenser of the at least one heat pump, such that heat is transferred to the feeding conduit 93 subsequently by the heat exchanger 22 and by the ground-coupled heat exchanger and/or by the condenser.

Instead of using an emergency cooler 4 coupled to the heating system 91, the emergency cooler 4 may be couplable to the coolant circuit 20. This way, the emergency cooler 4 may be configured to be controlled to, in use, cool the liquid coolant 25 before being pumped through the immersion enclosure 21 by the pump 23. The emergency cooler 4 may, for example, be couplable to the return conduit 26 of the coolant circuit 20 such that heat not transferred to the heating medium 96 in the heat exchanger 22 is removed from the liquid coolant 26 by the emergency cooler 4.

Instead of on the return conduit 92, a temperature sensor 41 may be arranged in the coolant circuit 20, for example on the return conduit 26, to measure a temperature signal representative for a return temperature of the liquid coolant returned via the return conduit 26 of the coolant circuit 20 before being pumped through the immersion enclosure 21.

In addition or alternative to a greenhouse, the system and method may be used for heating other buildings, such as a houses.

It should be understood that various changes and modifications to the presently preferred embodiments can be made without departing from the scope of the invention, and therefore will be apparent to those skilled in the art. It is therefore intended that such changes and modifications be covered by the appended claims.

1. A method for energy optimisation between computing modules and a greenhouse, other building or industrial process equipment to be heated, comprising the steps of:
placing a mobile unit at a site of the greenhouse, other building or industrial process equipment to be heated, wherein the mobile unit comprises one or more computing modules for performing computing tasks, a cooling arrangement for cooling the computing modules, and an electric connector for connecting the computing modules with an electricity source;
connecting the electric connector to the electricity source;
coupling the cooling arrangement to the greenhouse, other building or industrial process equipment to be heated;
performing computing tasks with the computing modules whereby heat is generated; and
guiding the generated heat away from the computing modules towards the greenhouse, other building or industrial process equipment to be heated,
wherein the cooling arrangement comprises one or more closed-loop coolant circuits having an immersion enclosure, a heat exchanger and a pump,
wherein the method further comprises the steps of:
arranging the computing modules in the immersion enclosure of each of the one or more coolant circuits; and
filling the immersion enclosure with liquid coolant to at least partially immerse the computing modules in the liquid coolant,
wherein the step of coupling the cooling arrangement to the greenhouse, other building or industrial process equipment to be heated comprises coupling the heat exchanger of each of the one or more coolant circuits to a heating system of the greenhouse, other building or industrial process equipment to be heated; and
wherein, during the step of performing computing tasks with the computing modules, the liquid coolant is pumped through the one or more coolant circuits, through the immersion enclosure along the computing modules that are at least partially immersed therein, such that the cooling arrangement cools the computing modules by means of immersion cooling with the liquid coolant taking in the generated heat and guiding it away from the computing modules to the heat exchanger to be transferred to a heating medium that flows through the heating system of the greenhouse, other building or industrial process equipment to be heated.

2. The method according to claim 1, further comprising the steps of:
determining a heat required for heating the greenhouse, other building or industrial process equipment; and
controlling the computing modules in dependence of determined required heat.

3. The method according to claim 2, wherein the computing modules have a rated power, and wherein the step of controlling the computing modules in dependence of determined required heat comprises adjusting the power consumption of the computing modules above the rated power.

4. The method according to claim 1, wherein the method further comprises the steps of:
placing an emergency cooler at the site of the greenhouse, other building or industrial process equipment to be heated; and
i) coupling the emergency cooler to the heating system, wherein the heating system is a closed-loop heating circuit, such that the emergency cooler is controllable to cool the heating medium before heat is transferred thereto in the heat exchanger, wherein the emergency cooler is coupled to a return conduit of the heating circuit such that heat returned from the greenhouse, other building or industrial process equipment to be heated via the return conduit is removed from the heating medium;
and/or
ii) coupling the emergency cooler to the coolant circuit, such that the emergency cooler is controllable to cool the liquid coolant before being pumped through the immersion enclosure, wherein the emergency cooler is coupled to a return conduit of the coolant circuit such that heat not transferred to the heating medium is removed from the liquid coolant,
for example wherein the emergency cooler comprises a heat pump and/or a ground-coupled heat exchanger.

5. The method according to claim 4, further comprising the steps of:
measuring a temperature signal representative for a return temperature of the heating medium returned via the return conduit of the heating system and/or representative for a return temperature of the liquid coolant returned via the return conduit of the coolant circuit before being pumped through the immersion enclosure; and
controlling the emergency cooler to be activated when the temperature signal exceeds a predetermined threshold value and/or to be deactivated when the temperature signal falls below a predetermined threshold value.

6. The method according to claim 1, wherein the electricity source comprises a combined heat-power generator (CHP) located on the site of the greenhouse, other building or industrial process equipment to be heated, in particular a fuel-driven CHP, such that the mobile unit is powered by the combined heat- and power generator, and such that the heating medium is heated by the combined heat- and power generator.

7. The method according to claim 6, wherein the step of coupling the heat exchanger of each of the one or more coolant circuits to the heating system of the greenhouse, other building or industrial process equipment to be heated comprises the step of coupling the heat exchanger with the CHP in series, such that, during the step of performing computing tasks with the computing modules, heat is transferred to the heating medium by the heat exchanger, and subsequently by the CHP to upgrade a temperature of the heating medium before flowing through the heating system of the greenhouse, other building or industrial process equipment to be heated.

8. The method according to claim 1, further comprising the steps of, before the step of performing computing tasks with the computing modules:
determining an expected heat required for heating the greenhouse, other building or industrial process equipment to be heated;
determining a number of the computing modules to be provided based on the expected heat required and an expected heat generation of each computing module;
arranging the determined number of computing modules in the immersion enclosure in the one or more coolant circuits in the mobile unit.

9. A mobile unit for energy optimisation between computing modules and a greenhouse, other building or industrial process equipment to be heated comprising:
a transportation container;
one or more computing modules to perform computing tasks whereby heat is generated;
a cooling arrangement couplable to the greenhouse, other building or industrial process equipment to be heated, to cool the computing modules and guiding heat away from the computing modules towards the greenhouse, other building or industrial process equipment to be heated; and
an electric connector for connecting the computing modules with an electricity source;
wherein the cooling arrangement is arranged in the transportation container and comprises one or more closed-loop coolant circuits having an immersion enclosure configured to enclose a liquid coolant, a heat exchanger and a pump,
wherein the computing modules are arranged in the immersion enclosure of each of the one or more coolant circuits to be at least partially immersed in the liquid coolant,
wherein the heat exchanger of each of the one or more coolant circuits is couplable to a heating system the greenhouse, other building or industrial process equipment to be heated, and
wherein the pump is configured to, when computing tasks are performed with the computing modules, pump the liquid coolant through the one or more coolant circuits, through the immersion enclosure along the computing modules that are at least partially immersed therein, such that the cooling arrangement is configured to cool the computing modules by means of immersion cooling with the liquid coolant taking in the generated heat and guiding it away from the computing modules to the heat exchanger to be transferred to a heating medium that flows through the heating system of the greenhouse, other building or industrial process equipment to be heated.

10. The mobile unit according to claim 9, comprising a controller operatively connected to the computing modules, wherein the controller is configured to determine a heat required for heating the heating the greenhouse, other building or industrial process equipment, and configured to control the computing modules in dependence of the determined required heat.

11. The mobile unit according to claim 10, wherein the computing modules have a rated power, and wherein the computing modules are configured to be controlled by the controller to adjust their power above the rated power.

12. The mobile unit according to claim 9, further comprising an emergency cooler,
couplable to a closed-loop heating circuit of the heating system, wherein the emergency cooler is configured to be controlled to, in use, cool the heating medium before heat is transferred thereto in the heat exchanger, wherein the emergency cooler is couplable to a return conduit of the heating circuit such that, in use, heat returned from the greenhouse, other building or industrial process equipment to be heated via the return conduit is removed from the heating medium by the emergency cooler; and/or
couplable to the coolant circuit, such that the emergency cooler is configured to be controlled to, in use, cool the liquid coolant before being pumped through the immersion enclosure, wherein the emergency cooler is couplable to a return conduit of the coolant circuit such that heat not transferred to the heating medium is removed from the liquid coolant by the emergency cooler,
for example wherein the emergency cooler comprises a heat pump and/or a ground-coupled heat exchanger.

13. The mobile unit according to claim 12, further comprising:
a temperature sensor to measure a temperature signal representative for a return temperature of the heating medium returned via the return conduit of the heating system and/or to representative for a return temperature of the liquid coolant returned via the return conduit of the coolant circuit before being pumped through the immersion enclosure; and
a controller to control the emergency cooler to be activated when the temperature signal exceeds a predetermined threshold value and/or to be deactivated when the temperature signal falls below a predetermined threshold value.

14. The mobile unit according to claim 9, comprising multiple coolant circuits,
wherein the heat exchangers of each of the coolant circuits are fluidly connected to each other to be couplable to the greenhouse, other building or industrial process equipment to be heated, for example in parallel; and/or
wherein the respective immersion enclosures of the coolant circuits are positioned above each other and/or side-by-side and/or in rows in the mobile unit,
in particular wherein a number of computing modules in each of the immersion enclosures is substantially the same.

15. The mobile unit according to claim 14, wherein the immersion enclosures of the coolant circuits are positioned in at least two rows in the mobile unit, wherein the mobile unit comprises an entrance, and a walking space that extends in the mobile unit from the entrance between the at least two rows of immersion enclosures,
in particular wherein the respective heat exchangers and/or the respective pumps of the coolant circuits are positioned in the mobile unit substantially in line with the at least two rows.

16. An assembly for energy optimisation between a mobile unit with computing modules and a greenhouse, other building or industrial process equipment to be heated, comprising:
the mobile unit according to claim 9;
the heating system of the greenhouse, other building or industrial process equipment to be heated coupled to the heat exchanger of each of the one or more coolant circuits of the mobile unit; and
an electricity source connected to the computing modules via the electric connector of the mobile unit,
wherein the electricity source comprises a combined heat-power generator (CHP) located on a site of the greenhouse, other building or industrial process equipment to be heated, in particular a fuel-driven CHP, such that the mobile unit is configured to be powered by the CHP, and such that, in use, the heating medium is heated by CHP.

17. The assembly according to claim 16, wherein the heat exchanger of each of the one or more coolant circuits that is coupled with the heating system of the greenhouse, other building or industrial process equipment to be heated is also coupled in series with the CHP, such that, in use, heat is transferred to the heating medium by the heat exchanger, and that the heating medium is subsequently guided along the CHP such that heat is subsequently transferred to the heating medium by the CHP to upgrade a temperature of the heating medium before flowing through the heating system of the greenhouse, other building or industrial process equipment to be heated.

18. The assembly according to claim 16, wherein the heating system of the greenhouse, other building or industrial process equipment to be heated comprises a high-temperature heat buffer and/or wherein the heating system is a high-temperature heating system.

19. A method comprising:
utilizing an assembly according to claim 16 for energy optimisation between computing modules and a greenhouse, other building or industrial process equipment to be heated.

20. A method comprising:
utilizing a mobile unit according to claim 9 for balancing a voltage and/or a frequency of the electricity source.
